(19) United States
(12) Patent Application Publication
(10) Pub. No.: US 2019/0042112 A1
(43) Pub. Date: Feb. 7, 2019

(54) DATA STORAGE DEVICE WITH DEFECTIVE DIE INDICATOR

(71) Applicant: Intel Corporation, Santa Clara, CA (US)

(72) Inventors: Sarvesh Varakabe Gangadhar, Santa Clara, CA (US); Feng Zhu, San Jose, CA (US); Xin Guo, San Jose, CA (US); Simon D. Ramage, Vancouver BC (CA); Ning Wu, Folsom, CA (US); Robert E. Frickey, III, Sacramento, CA (US)

(21) Appl. No.: 15/927,042

(22) Filed: Mar. 20, 2018

(51) Int. Cl. G06F 3/06; G11C 16/34; G06F 11/30

(52) U.S. Cl. CPC G06F 3/0619; G06F 3/0653; G06F 11/3037; G11C 16/349; G06F 3/0679

(57) ABSTRACT

Embodiments of the present disclosure may relate to a data storage controller that may include a non-volatile memory, and a processor coupled with the non-volatile memory to perform a scan of a plurality of non-volatile memory dies in a multi-die memory package to detect one or more defective non-volatile memory dies, where an individual non-volatile memory die of the plurality of non-volatile memory dies is defective if the individual non-volatile memory die has a number of bad blocks that exceeds a predefined threshold, and store one or more defective die indicators in a die topology in the non-volatile memory based at least in part on the scan, where the one or more defective die indicators correspond to the one or more defective non-volatile memory dies. Other embodiments may be described and/or claimed.

### FIELD

Embodiments of the present disclosure generally relate to the field of computer data storage devices and, more particularly, to devices and techniques for die topology creation and use in data storage devices.

### BACKGROUND

To meet the demand for increased solid-state drive (SSD) capacity, NAND packages with higher stack heights have been developed and incorporated into SSDs. However, higher stacks are associated with increased incidence of one or more defective dies in the NAND package, which may be referred to as a partial package when there are one or more defective dies. Typically, partial packages have been diverted to other uses during the SSD manufacturing process rather than being included in the SSD devices (e.g., by selling them for other uses). Partial packages not incorporated into SSDs are sold with a significantly lower margin than SSDs, resulting in increased overall manufacturing costs and lower profitability.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 depicts a block diagram of a data storage device including non-volatile memory defective die detection capability, in accordance with various embodiments.

FIG. 2 is a flow diagram of a technique for creating a die topology with a data storage device, in accordance with various embodiments.

FIG. 3 is a flow diagram of a technique for excluding defective dies during a data storage device power-on procedure, in accordance with various embodiments.

FIG. 4 is a block diagram that schematically illustrates a computing device, in accordance with various embodiments.

FIG. 5 illustrates an example storage medium with instructions configured to enable an apparatus to practice various aspects of the present disclosure, in accordance with various embodiments.

### DETAILED DESCRIPTION

Embodiments of the present disclosure may relate to a data storage device that may include a memory package having a plurality of non-volatile memory dies and a data storage controller. In some embodiments, the data storage controller may perform a scan of the plurality of non-volatile memory dies to detect one or more defective non-volatile memory dies. In various embodiments, an individual non-volatile memory die of the plurality of non-volatile memory dies may be considered to be defective if the individual non-volatile memory die has a number of bad blocks that exceeds a predefined threshold (e.g., 50 bad blocks, or any other suitable number of bad blocks). In some embodiments, a bad block may be a block that includes one or more invalid bits with uncertain reliability and/or that cannot be error corrected. In various embodiments, the data storage controller may store one or more defective die indicators in a die topology in a non-volatile memory based at least in part on the scan. In some embodiments, the one or more defective die indicators may correspond to the one or more defective non-volatile memory dies. In various embodiments, a defective die may be responsive to NAND commands, in similar fashion to a good die. In some embodiments, a die that does not respond to NAND commands may be referred to as a missing die.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

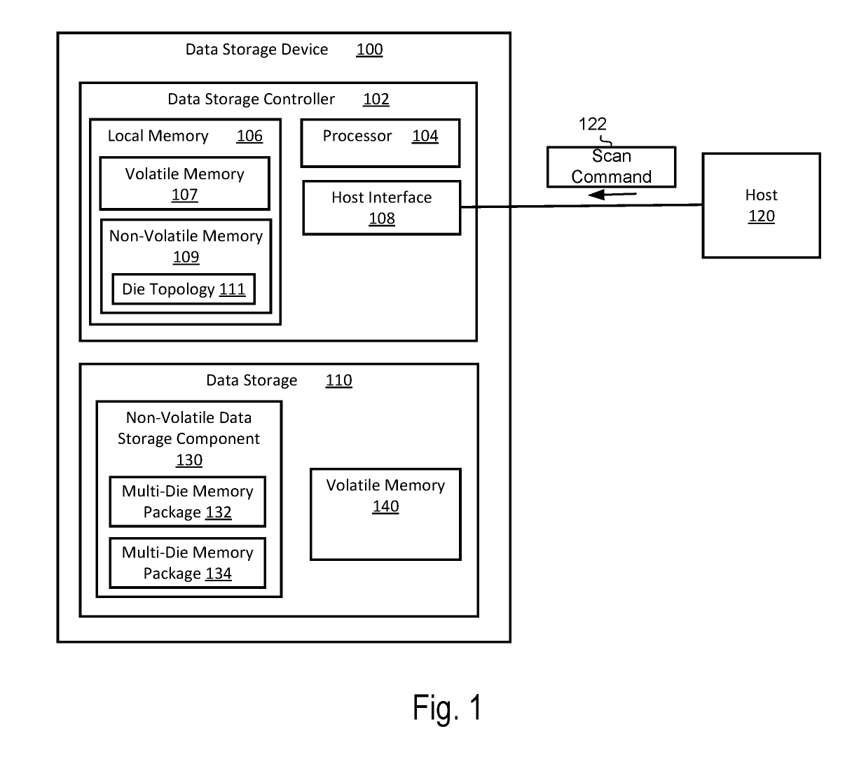

FIG. 1 depicts a block diagram of a data storage device 100 that may include a non-volatile memory die topology generation capability, in accordance with various embodiments. In some embodiments, the data storage device 100 may include a data storage controller 102 and a data storage 110, which may include a non-volatile data storage component 130 (e.g., non-volatile memory (NVM)) and a volatile memory 140, in accordance with various embodiments.

In some embodiments, the non-volatile data storage component 130 may include a first multi-die memory package 132 and a second multi-die memory package 134. Although two multi-die memory packages are shown, it should be understood that any suitable number of multi-die memory packages may be used in various embodiments, including a single multi-die memory package or more than two multi-die memory packages. In various embodiments, the first multi-die memory package 132 and the second multi-die memory package 134 may be NAND memory packages that each include a plurality of NAND memory dies. The multi-die memory packages 132, 134 may include any suitable number of dies and may include dual die packages (DDPs), quad die packages (QDPs), octal die packages (ODPs), and/or packages with a different number of dies such as 16 die packages (hexadecimal die packages (HDPs)) or 32 die packages (DPs). In various embodiments, one or more of the first multi-die memory package 132 and the second multi-die memory package 134 may be a partial package that may include one or more defective dies. In some embodiments, a partial package may be referred to in terms of the number of non-defective dies in the package (e.g., an ODP with one defective die may be referred to as a 7DP).

The data storage controller 102 of the data storage device 100 may be embodied as any type of control device, circuitry, or collection of hardware devices capable of performing data operations (e.g., write, read, and/or copy) on the non-volatile data storage component 130. In some embodiments, the data storage controller 102 may include a processor or processing circuitry 104, local memory 106, and a host interface 108. In some embodiments, a host 120 may be communicatively coupled with the data storage controller 102 of the data storage device 100 via the host interface 108. In various embodiments, the data storage controller 102 may include additional devices, circuits, and/or components commonly found in a drive controller of a data storage device such as a solid state drive (SSD). In various embodiments, the local memory 106 may include a volatile memory 107 and/or a non-volatile memory 109. In some embodiments, the processor or processing circuitry 104 may be communicatively coupled with the local memory 106 and/or the host interface 108.

In some embodiments, the data storage controller 102 may perform a die topology generation operation in response to a request from the host 120 (e.g., as part of a manufacturing flow). In embodiments, the die topology generation operation may result in a die topology 111, which may also be referred to as a die map, being stored in the non-volatile memory 109 or any other suitable non-volatile memory location. In some embodiments, the die topology 111 may be stored in flash memory via a serial programming interface (SPI). In some embodiments, the die topology 111 may contain information relating to all non-volatile memory dies in the data storage 110. In embodiments, the information relating to the non-volatile memory dies may include a memory package identifier, a die identifier, a defective die indicator, a retired die indicator, and/or any other suitable information relating to the non-volatile memory dies. In various embodiments, the host 120 may issue a scan command 122 from the host 120 to the data storage device 100 via the host interface 108. In some embodiments, the data storage controller 102 may perform a scan of each of a plurality of non-volatile memory dies in the multi-die memory packages 132 and 134 of the non-volatile data storage component 130. In various embodiments, all responsive non-volatile memory dies (both good and bad dies) in the multi-die memory packages 132 and 134 may be scanned. In various embodiments, processor 104 of the data storage controller 102 may perform the scan based at least in part on the scan command 122. In some embodiments, the processor 104 may perform the scan to detect one or more defective non-volatile memory dies, where an individual non-volatile memory die of the plurality of non-volatile memory dies is defective if the individual non-volatile memory die has a number of bad blocks that exceeds a predefined threshold. In various embodiments, the processor 104 may store one or more defective die indicators in the die topology 111 in the non-volatile memory 109 based at least in part on the scan, where the one or more defective die indicators correspond to the one or more defective non-volatile memory dies. In some embodiments, an initial or default die topology may be present, and the data storage controller may update the initial or default die topology rather than create a new one.

In various embodiments, the processor 104 may also determine a number of good dies for each of a plurality of memory channels, and may generate an indicator in response to the number of good dies for each of the plurality of memory channels does not meet one or more predetermined channel requirements. In some embodiments, a particular die of the plurality of non-volatile memory dies may be determined to be a good die in response to the particular die does not have a number of bad blocks that exceeds the predefined threshold. In various embodiments, the one or more predetermined channel requirements may include a number of good dies expected for each channel, and the processor 104 may be to generate the indicator in response to the number of good dies in a channel is less than the number of good dies expected for the channel. In some embodiments, the processor 104 may generate one or more retired die indicators in response to the number of good dies in a channel is more than the number of good dies expected for the channel, and may store the one or more retired die indicators in the die topology 111.

In various embodiments, the processor 104 may read the die topology 111 from the non-volatile memory 109 in response to detection of a power-on operation of the data storage device 100. In some embodiments, the processor 104 may read the die topology 111 via a serial peripheral interface (SPI), not shown for clarity. In some embodiments, the processor 104 may fetch a defective die list that may include the one or more defective die indicators from the die topology 111, and may update a healthy die list that excludes one or more non-volatile memory dies (e.g., defective dies in multi-die memory package 132 and/or multi-die memory package 134) from being accessed during read and write operations of the data storage device 100, based at least in part on the defective die list, where the healthy die list includes dies that do not have a number of bad blocks that exceed the predefined threshold. In various embodiments, the processor 104 may store the updated healthy die list in the local memory 106 (e.g., in volatile memory 107 and/or non-volatile memory 109). In some embodiments, the processor 104 may read the die topology 111 every time the data storage device 100 powers on or restarts (e.g., during a NAND die discovery operation), and may exclude defective dies as indicated in the die topology 111 from future use (e.g., read and write operations). In various embodiments, the data storage device 100 may include one or more firmware modules (e.g., implemented in data storage controller 102) that may not be aware of defective dies that have been excluded from use, which may result in increased operating efficiency by eliminating the need to mask the defective dies during operation, and associated processing and/or memory that otherwise may be used to do so. In some embodiments, detecting, marking, and excluding defective dies from use may allow the data storage device 100 to be used as a regular data storage device while meeting standard manufacturing process requirements (e.g., a consistent number of good dies per channel and/or per data storage device), which may result in a data storage device with one or more partial packages having a performance level equivalent to a data storage device that does not include any partial packages.

The data storage device 100 may be embodied as any type of device capable of storing data and performing the functions described herein. In some embodiments, the data storage device 100 may be embodied as a solid-state drive (SSD) and/or the data storage controller 102 may be a SSD controller. In other embodiments, the data storage device 100 may embodied as some other form of non-volatile memory (NVM) storage.

The processor 104 may be embodied as any type of processor capable of performing the functions described herein. For example, the processor 104 may be embodied as a single or multi-core processor(s), digital signal processor, microcontroller, or other processor or processing/controlling circuit. Similarly, the local memory 106 may be embodied as any type of volatile and/or non-volatile memory or data storage capable of performing the functions described herein. In some embodiments, the local memory 106 may store firmware and/or other instructions executable by the processor 104 to perform the described functions of the data storage controller 102. In some embodiments, the processor 104 and the local memory 106 may form a portion of a System-on-a-Chip (SoC) and be incorporated, along with other components of the data storage controller 102, onto a single integrated circuit chip.

The host interface 108 may also be embodied as any type of hardware processor, processing circuitry, input/output circuitry, and/or collection of components capable of facilitating communication of the data storage device 100 with a host device (e.g., host 120) or service (e.g., a host application). That is, the host interface 108 may embody or establish an interface for accessing data stored on the data storage device 100 (e.g., stored in the data storage 110). In various embodiments, the host interface 108 may be configured to utilize any suitable communication protocol and/or technology to facilitate communications with the data storage device 100 depending on the type of data storage device. In some embodiments, the host interface 108 may be configured to communicate with a host device or service using Serial Advanced Technology Attachment (SATA), Peripheral Component Interconnect express (PCIe), Serial Attached SCSI (SAS), Universal Serial Bus (USB), and/or other communication protocol and/or technology.

In various embodiments, the non-volatile data storage component 130 may be embodied as any type of data storage capable of storing data in a persistent manner. For example, in the some embodiments, the non-volatile data storage component 130 may be embodied as non-volatile memory (NVM) and may be referred to herein as non-volatile memory 130 with the understanding that the non-volatile data storage component 130 may be embodied as other types of persistent data storage, in other embodiments. In some embodiments, the non-volatile data storage component 130 may be a block-based memory. The non-volatile memory 130 may be embodied as NAND flash memory, NOR flash memory, phase change memory (PCM), electrically erasable programmable read-only memory (EEPROM), resistive memory, nanowire memory, three-dimensional cross point memory arrays, ferro-electric transistor random access memory (FeTRAM), magnetoresistive random access memory (MRAM), spin transfer torque MRAM, and/or other non-volatile memory.

The volatile memory 140 may be embodied as any type of memory capable of storing data while the data storage device 100 is in operation. For example, the volatile memory 140 may be embodied as dynamic random access memory (DRAM), static random access memory (SRAM), or other type of volatile memory in various embodiments.

While the description herein with respect to some embodiments is written in the context of a NAND based SSD, it should be understood that the concepts may apply to other block-based storage subsystems that include multi-die memory packages (e.g., Direct-Access SSDs, redundant array of independent disks (RAID)-Arrays, 3-D crosspoint (3DXP) based SSDs, network attached storage (NAS) and storage area network (SAN) devices.)

An environment may be established by the data storage device 100, in accordance with various embodiments. In some embodiments, the environment may include one or modules. Each of the modules and/or other components of the environment may be embodied as firmware, software, hardware, or a combination thereof. In some embodiments, the various modules, logic, and other components of the environment may form a portion of, or otherwise be established by, the data storage controller 102 or other hardware components of the data storage device 100. As such, in some embodiments, any one or more of the modules of the environment may be embodied as a circuit or collection of electrical devices.

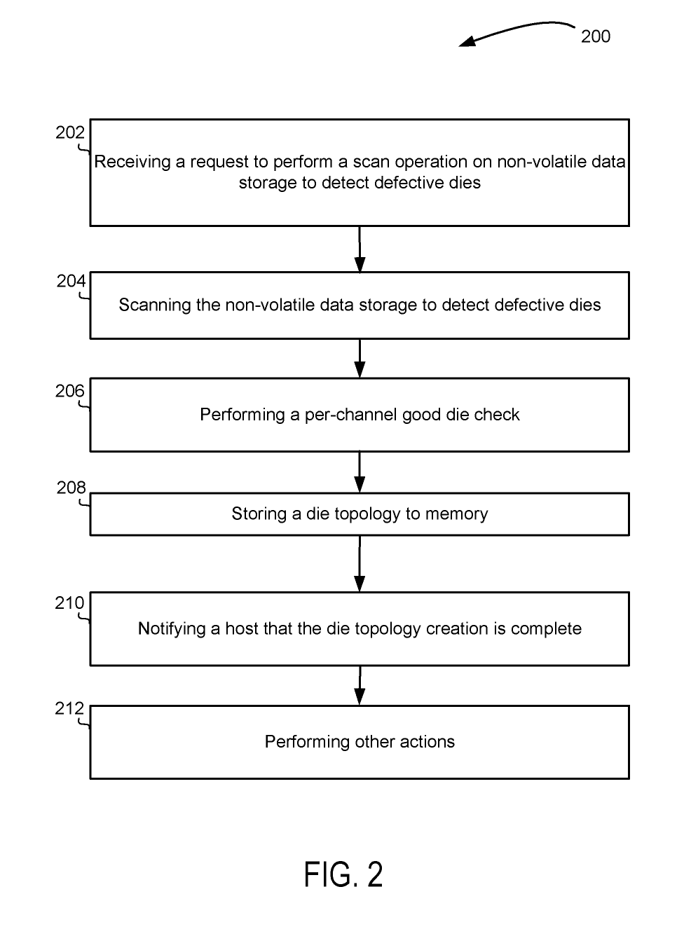

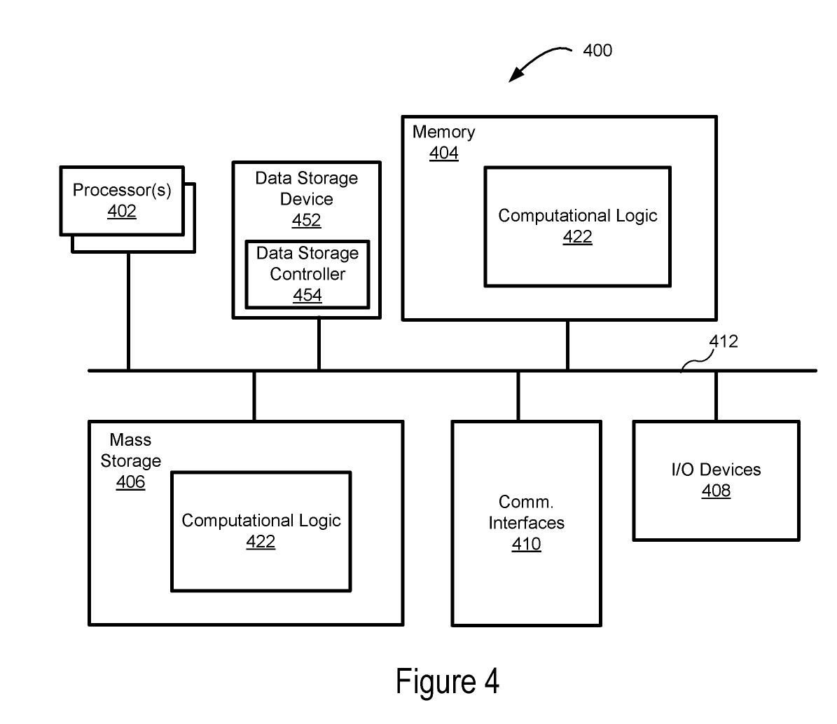

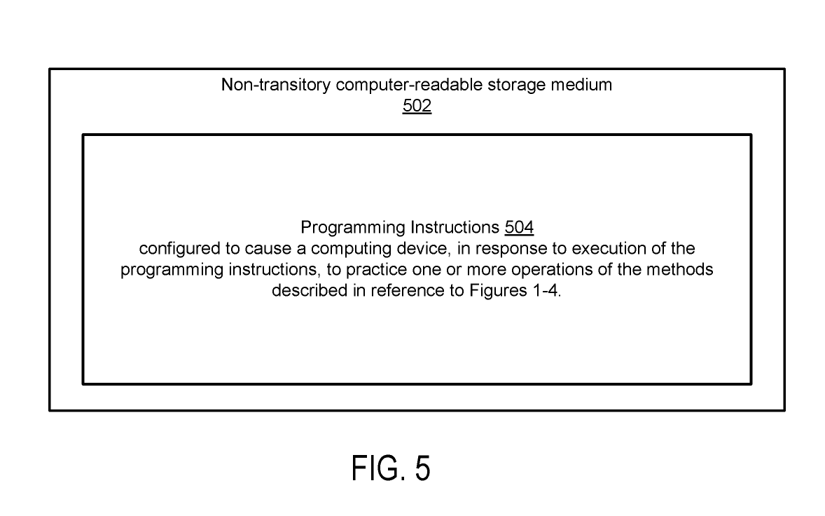

FIG. 2 is a flow diagram of a technique 200 for creating a die topology (e.g., die topology 111) with a data storage device (e.g., data storage device 100), in accordance with various embodiments. In some embodiments, some or all of the technique 200 may be practiced by components shown and/or described with respect to the data storage device 100 of FIG. 1, the computing device 400 of FIG. 4, or some other component described with respect to FIGS. 1 and/or FIGS. 4-5. In some embodiments, the technique 200 may be performed once during a data storage device preparation operation as a part of a manufacturing flow.

In various embodiments, at a block 202, the technique 200 may include receiving a request to perform a scan operation on non-volatile data storage to detect defective dies (e.g., scan command 122 from host 120). In some embodiments, at a block 204, the technique 200 may include scanning the non-volatile data storage (e.g., non-volatile data storage component 130) to detect defective dies (e.g, defective dies in the multi-die memory package 132 and the multi-die memory package 134) in response to the request to perform the scan operation. In some embodiments, the data storage controller 102 may scan the first multi-die memory package 132 and the second multi-die memory package 134 by reading a one-time programmable (OTP) page of each die to determine the number of bad blocks in the die, and may mark a die as defective (e.g., with a defective die indicator) in response to the number of bad blocks for the die is greater than a predefined threshold. In some embodiments, the predefined threshold may be an input value associated with a stored configuration token. In some embodiments, the stored configuration token may be an FConfig token and/or may be designated with a parameter of Defective block threshold.

In various embodiments, at a block 206, the technique 200 may include performing a per-channel good die check. In some embodiments, the data storage controller 102 (e.g., with processor 104) may determine a number of good dies for each of a plurality of memory channels, and may generate an indicator if the number of good dies for each of the plurality of memory channels does not meet one or more predetermined channel requirements. In some embodiments, the one or more predetermined channel requirements may include a number of good dies expected for each channel, and the data storage controller 102 may be to generate the indicator in response to the number of good dies in a channel is less than the number of good dies expected for the channel. In various embodiments, the number of good dies expected for the channel may be an input value associated with a stored configuration token. In some embodiments, the stored configuration token may be an FConfig token and/or may be designated with a parameter of Number_of_dies_in_ChannelX, where X corresponds to a channel number. In some embodiments, the data storage controller may generate one or more retired die indicators in response to the number of good dies in a channel is more than the number of good dies expected for the channel, and may store the one or more retired die indicators in the die topology (e.g., die topology 111). Although the defective die indicator and the retired die indicator are mentioned as being separate types of indicators, in some embodiments a common type of indicator may be used for both purposes discussed above where the common indicator is to indicate that a die should not be used regardless whether it is in response to the die having a number of bad blocks that exceeds Defective_block_threshold or in response to being trimmed due to a greater number of dies being present in a channel than expected according to Number_of_dies_in_ChannelX.

In embodiments, at a block 208, the technique 200 may include storing a die topology (e.g, die topology 111) to memory. In various embodiments, storing the die topology to memory may include associating one or more defective die indicators with one or more non-volatile memory die identifiers in the die topology, based at least in part on the scan performed at the block 204, and storing the non-volatile memory die topology in a non-volatile memory (e.g., non-volatile memory 109). In various embodiments, storing the non-volatile memory die topology may also include storing one or more retired die indicators for dies trimmed in response to exceeding Number_of_dies_in_ChannelX and/or may include storing one or more common indicators that indicate one or more dies should not be used. In some embodiments, at a block 210, the technique 200 may include notifying a host (e.g., the host from which the request to perform the scan operation was received at the block 202) that the die topology creation is complete.

In some embodiments, one or more of the actions performed with the technique 200 may be performed on a per-channel basis. In various embodiments, each channel may be scanned one by one to detect defective dies at the block 204, followed by performing a per-channel good die check at the block 206 for the channel, then looping back through the block 204 and the block 206 for each additional channel, with the die topology stored in non-volatile memory at the block 208 after the scanning and per-channel good die checks have been performed for all channels. In some embodiments, for each channel, the OTP page of each die may be read to determine the number of defective blocks for each die. The number of defective blocks for each die may then be compared with the input Defective block threshold. If the number of defective blocks for a particular die is more than the Defective block threshold input value, the die may be marked as bad in the die topology. In some embodiments, die blocks may be referred to as bad or defective blocks interchangeably, and/or dies having a number of bad blocks that exceeds Defective block threshold may be referred to as bad or defective dies interchangeably. In various embodiments, the number of good dies in the channel may be counted.

In some embodiments, performing a per-channel good-die check at the block 206 may be performed for a particular channel if there is at least one bad die in the channel, and may not be performed if the channel does not include at least one bad die. In various embodiments, if there is at least one bad die in the channel, one or more additional checks may be performed. In some embodiments, if the number of good dies is less than the input Number_of_dies_in_ChannelX, the data storage device (e.g., SSD) may be asserted (prevented from entering service) and an indicator may be generated to indicate that there are more bad and/or missing dies than expected, resulting in the number of good dies for the channel to be less than required. In some embodiments, if the number of good dies is more than the input Number_of_dies_in_ChannelX, the data storage device may also be asserted, with an indication that the channel has more good dies than expected. In other embodiments, the data storage device may not be asserted if the number of good dies is more than the input Number_of_dies_in_ChannelX, but one or more dies may be trimmed and/or marked as a factory retired die (e.g., in die topology 111) such that the channel will use the expected number of good dies when the data storage device is in use, with the data storage controller 102 excluding the trimmed dies along with any other dies marked as defective in the die topology 111. In various embodiments, the retired dies may not be used in data storage device 100 operations (e.g., read and write operations) and/or may not be recognized by one or more firmware modules operating in the data storage device 100. In some embodiments, after the dies in all channels have been scanned and any needed per-channel good die checks have been performed, a check may be performed to determine whether the total number of good dies for all channels is equal to the sum of all the Number_of_dies_in_ChannelX input values. In various embodiments, the data storage device may be asserted if the total number of good dies for all channels does not equal the sum of all the Number_of_dies_in_ChannelX input values.

In various embodiments, at a block 212, the technique 200 may include performing one or more other actions. In some embodiments, the one or more additional actions performed at the block 212 may include performing one or more screening techniques such as attempting to read the created and stored die topology, and screening the data storage device from further use if the die topology cannot be found or read, or if the data storage device is in a trapped state for some other reason. In some embodiments, the data storage device may also be screened from further use (e.g., asserted) if the non-volatile data storage component 130 is found to contain one or missing dies (e.g., dies that do not respond to NAND commands), or may be screened from further use if the number of good dies in one or more channels was found, at the block 206, to be less than the number of good dies expected for the one or more channels.

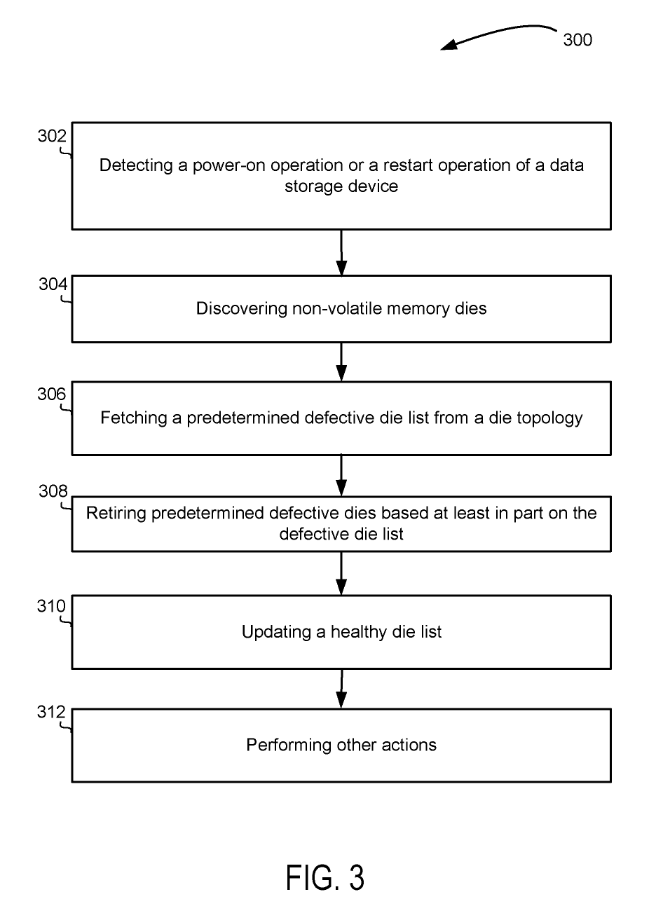

FIG. 3 is a flow diagram of a technique 300 for excluding defective dies during a data storage device power-on procedure, in accordance with various embodiments. In some embodiments, some or all of the technique 300 may be practiced by components shown and/or described with respect to the data storage device 100 of FIG. 1, the computing device 400 of FIG. 4, or some other component described with respect to FIGS. 1 and/or FIGS. 4-5. In some embodiments, at a block 302, the technique 300 may include detecting a power-on operation or a restart operation of a data storage device. In some embodiments, the processor 104 of the data storage controller 102 may detect a power-on operation or a restart operation of the data storage device 100. In various embodiments, at a block 304, the technique 300 may include discovering non-volatile memory dies (e.g., dies in the multi-die memory package 132 and the multi-die memory package 134). In some embodiments, at a block 306, the technique 300 may include fetching a predetermined defective die list from a die topology (e.g., die topology 111). In various embodiments, at a block 308, the technique 300 may include retiring predetermined defective dies based at least in part on the defective die list. In some embodiments, at a block 310, the technique 300 may include updating a healthy die list. In some embodiments, the healthy die list may be updated by excluding the dies retired at the block 308 from the healthy die list. In some embodiments, the healthy die list may also be updated by excluding dies marked as retired as part of a per-channel good die check (e.g., the per-channel good die check performed at the block 206 of FIG. 2). In some embodiments, updating the healthy die list may include storing the updated healthy die list in local memory 106 or any other suitable storage location. In various embodiments, at a block 312, the technique 300 may include performing one or more other actions. In various embodiments, the technique 300 may be performed every time the data storage device 100 powers on. In some embodiments, one or more aspects of the technique 300 may also be performed at the time of manufacture, as an additional data storage device check and/or preparation process after the technique 200 has been performed.

FIG. 4 illustrates a block diagram of an example computing device 400 suitable for use with various components of FIG. 1, the technique 200 of FIG. 2, and/or the technique 300 of FIG. 3, in accordance with various embodiments. For example, the computing device 400 may be, or may include or otherwise be coupled to, data storage device 100, data storage controller 102, data storage 110, and/or one or more other components shown and/or described with respect to FIG. 1. As shown, computing device 400 may include one or more processors or processor cores 402 and system memory 404. For the purpose of this application, including the claims, the terms “processor” and “processor cores” may be considered synonymous, unless the context clearly requires otherwise. The processor 402 may include any type of processors, such as a central processing unit (CPU), a microprocessor, and the like. The processor 402 may be implemented as an integrated circuit having multi-cores, e.g., a multi-core microprocessor. In some embodiments, processors 402, in addition to cores, may further include hardware accelerators, e.g., hardware accelerators implemented with Field Programmable Gate Arrays (FPGA). The computing device 400 may include mass storage devices 406 (such as diskette, hard drive, non-volatile memory (NVM) (e.g., compact disc read-only memory (CD-ROM), digital versatile disk (DVD), any other type of suitable NVM, and so forth). In general, system memory 404 and/or mass storage devices 406 may be temporal and/or persistent storage of any type, including, but not limited to, volatile and non-volatile memory, optical, magnetic, and/or solid state mass storage, and so forth. Volatile memory may include, but is not limited to, static and/or dynamic random access memory (DRAM). Non-volatile memory may include, but is not limited to, electrically erasable programmable read-only memory, phase change memory, resistive memory, and so forth.

The computing device 400 may further include I/O devices 408 (such as a display (e.g., a touchscreen display), keyboard, cursor control, remote control, gaming controller, image capture device, and so forth) and communication interfaces 410 (such as network interface cards, modems, infrared receivers, radio receivers (e.g., Bluetooth), and so forth), one or more antennas, and/or any other suitable component.

The communication interfaces 410 may include communication chips (not shown) that may be configured to operate the computing device 400 in accordance with a local area network (LAN) (e.g., Ethernet) and/or a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 410 may operate in accordance with other wireless protocols in other embodiments.

In various embodiments, computing device 400 may include a data storage device 452 that may be configured in similar fashion to the data storage device 100 described with respect to FIG. 1. In some embodiments, the data storage device 452 may be coupled with other components of the computing device 400. In some embodiments, the data storage device 452 may include a data storage controller 454 that may be configured in similar fashion to the data storage controller 102 described with respect to FIG. 1.

The above-described computing device 400 elements may be coupled to each other via system bus 412, which may represent one or more buses. In the case of multiple buses, they may be bridged by one or more bus bridges (not shown). Each of these elements may perform its conventional functions known in the art. In particular, system memory 404 and mass storage devices 406 may be employed to store a working copy and a permanent copy of the programming instructions for the operation of various components of computing device 400, including but not limited to an operating system of computing device 400, one or more applications, and/or operations associated with computing device 400 serving as data storage controller 454, collectively denoted as computational logic 422. The various elements may be implemented by assembler instructions supported by processor(s) 402 or high-level languages that may be compiled into such instructions. In some embodiments, the computing device 400 may be implemented as a fixed function ASIC, a FPGA, or any other suitable device with or without programmability or configuration options.

The permanent copy of the programming instructions may be placed into mass storage devices 406 in the factory, or in the field through, for example, a distribution medium (not shown), such as a compact disc (CD), or through communication interface 410 (from a distribution server (not shown)). That is, one or more distribution media having an implementation of the agent program may be employed to distribute the agent and to program various computing devices.

The number, capability, and/or capacity of the elements 408, 410, 412 may vary, depending on whether computing device 400 is used as a stationary computing device, such as a set-top box or desktop computer, or a mobile computing device, such as a tablet computing device, laptop computer, game console, or smartphone. Their constitutions are otherwise known, and accordingly will not be further described.

For some embodiments, at least one of processors 402 may be packaged together with computational logic 422 configured to practice aspects of embodiments described herein to form a System in Package (SiP) or a System on Chip (SoC).

In various implementations, the computing device 400 may comprise one or more components of a data center, a laptop, a netbook, a notebook, an ultrabook, a smartphone, a tablet, an ultra mobile PC, or a mobile phone. In some embodiments, the computing device 400 include one or more components of a server. In further implementations, the computing device 400 may be any other electronic device that processes data.

FIG. 5 illustrates example computer-readable storage medium 502 having instructions configured to practice all or selected ones of the operations associated with the computing device 400, earlier described with respect to FIG. 4; the data storage device 100 and/or the data storage controller 102 described with respect to FIG. 1; the technique 200 described with respect to FIG. 2; and/or the technique 300 of FIG. 3, in accordance with various embodiments. As illustrated, computer-readable storage medium 502 may include a number of programming instructions 504. The storage medium 502 may represent a broad range of non-transitory persistent storage medium known in the art, including but not limited to flash memory, dynamic random access memory, static random access memory, an optical disk, a magnetic disk, etc. Programming instructions 504 may be configured to enable a device, e.g., data storage device 100, data storage controller 102 and/or other components of the data storage device 100, in response to execution of the programming instructions 504, to perform, e.g., but not limited to, various operations described for the data storage controller 102, the computing device 400 of FIG. 4, or operations shown and/or described with respect to technique 200 of FIG. 2 and/or technique 300 of FIG. 3. In alternate embodiments, programming instructions 504 may be disposed on multiple computer-readable storage media 502. In an alternate embodiment, storage medium 502 may be transitory, e.g., signals encoded with programming instructions 504.

Referring back to FIG. 4, for an embodiment, at least one of processors 402 may be packaged together with memory having all or portions of computational logic 422 configured to practice aspects shown or described for the data storage controller 102 and/or other components of the data storage device 100 shown in FIG. 1, operations shown or described with respect to the technique 200 of FIG. 2, and/or operations shown or described with respect to the technique 300 of FIG. 3. For an embodiment, at least one of processors 402 may be packaged together with memory having all or portions of computational logic 422 configured to practice aspects described for the data storage controller 102 and/or other components of the data storage device 100 shown in FIG. 1, operations shown or described with respect to the technique 200 of FIG. 2, and/or operations shown or described with respect to the technique 300 of FIG. 3 to form a System in Package (SiP). For an embodiment, at least one of processors 402 may be integrated on the same die with memory having all or portions of computational logic 422 configured to practice aspects described for the data storage controller 102 and/or other components of the data storage device 100 shown in FIG. 1, operations shown or described with respect to the technique 200 of FIG. 2 and/or operations shown or described with respect to the technique 300 of FIG. 3. For an embodiment, at least one of processors 402 may be packaged together with memory having all or portions of computational logic 422 configured to practice aspects of the data storage controller 102 and/or other components of the data storage device 100 shown in FIG. 1, operations shown or described with respect to the technique 200 of FIG. 2, and/or operations shown or described with respect to the technique 300 of FIG. 3 to form a System on Chip (SoC).

Machine-readable media (including non-transitory machine-readable media, such as machine-readable storage media), methods, systems and devices for performing the above-described techniques are illustrative examples of embodiments disclosed herein. Additionally, other devices in the above-described interactions may be configured to perform various disclosed techniques.

### EXAMPLES

Example 1 may include a data storage controller comprising: a non-volatile memory; and a processor coupled with the non-volatile memory to: perform a scan of a plurality of non-volatile memory dies in a multi-die memory package to detect one or more defective non-volatile memory dies, wherein an individual non-volatile memory die of the plurality of non-volatile memory dies is defective if the individual non-volatile memory die has a number of bad blocks that exceeds a predefined threshold; and store one or more defective die indicators in a die topology in the non-volatile memory based at least in part on the scan, wherein the one or more defective die indicators correspond to the one or more defective non-volatile memory dies.

Example 2 may include the subject matter of Example 1, or some other example herein, wherein the non-volatile memory dies are NAND memory dies.

Example 3 may include the subject matter of any one of Examples 1-2, or some other example herein,wherein the data storage controller includes a host interface and the processor is to perform the scan based at least in part on a scan command received from a host via the host interface.

Example 4 may include the subject matter of any one of Examples 1-3, or some other example herein, wherein the predefined threshold is an input value associated with a stored configuration token.

Example 5 may include the subject matter of any one of Examples 1-4, or some other example herein, wherein the processor is to read a one-time programmable (OTP) page of each die to determine the number of bad blocks in the die.

Example 6 may include the subject matter of any one of Examples 1-5, or some other example herein, wherein the processor is also to determine a number of good dies for each of a plurality of memory channels, and generate an indicator in response to a determination that the number of good dies for each of the plurality of memory channels does not meet one or more predetermined channel requirements, wherein a particular die of the plurality of non-volatile memory dies is determined to be a good die in response to a determination that the particular die has a number of bad blocks that is less than or equal to the predefined threshold.

Example 7 may include the subject matter of Example 6, or some other example herein, wherein the one or more predetermined channel requirements include a number of good dies expected for each channel, and the processor is to generate the indicator in response to a determination that the number of good dies in a channel is less than the number of good dies expected for the channel.

Example 8 may include the subject matter of any one of Examples 1-6, or some other example herein, wherein the processor is also to: generate one or more retired die indicators in response to a determination that the number of good dies in a channel is more than the number of good dies expected for the channel; and store the one or more retired die indicators in the die topology.

Example 9 may include the subject matter of any one of Examples 1-8, or some other example herein, wherein the processor is also to: read the die topology from the non-volatile memory in response to detection of a power-on operation of a data storage device that includes the data storage controller; fetch a defective die list that includes the one or more defective die indicators from the die topology; and update a healthy die list that excludes one or more of the plurality of non-volatile memory dies from being accessed during read and write operations, based at least in part on the defective die list, wherein the healthy die list includes dies that do not have a number of bad blocks that exceed the predefined threshold.

Example 10 may include the subject matter of any one of Examples 1-9, or some other example herein, wherein the data storage controller is a solid-state drive (SSD) controller.

Example 11 may include a data storage device comprising: a memory package having a plurality of non-volatile memory dies; and a data storage controller to: perform a scan of the plurality of non-volatile memory dies to detect one or more defective non-volatile memory dies, wherein an individual non-volatile memory die of the plurality of non-volatile memory dies is defective if the individual non-volatile memory die has a number of bad blocks that exceeds a predefined threshold; and store one or more defective die indicators in a die topology in a non-volatile memory based at least in part on the scan, wherein the one or more defective die indicators correspond to the one or more defective non-volatile memory dies.

Example 12 may include the subject matter of Example 11, or some other example herein, wherein the memory package is a NAND memory package.

Example 13 may include the subject matter of any one of Examples 11-12, or some other example herein, wherein the data storage controller is also to perform the scan based at least in part on a scan command received from a host.

Example 14 may include the subject matter of any one of Examples 11-13, or some other example herein, wherein the data storage controller is to read a one-time programmable page (OTP) page of each die to determine the number of bad blocks in each die.

Example 15 may include the subject matter of any one of Examples 11-14, or some other example herein, wherein the data storage controller is also to determine a number of good dies for each of a plurality of memory channels, and generate an indicator in response to a determination that the number of good dies for each of the plurality of memory channels does not meet one or more predetermined channel requirements, wherein a particular die of the plurality of non-volatile memory dies is determined to be a good die in response to a determination that the particular die has a number of bad blocks that is less than or equal to the predefined threshold.

Example 16 may include the subject matter of any one of Examples 11-15, or some other example herein, wherein the data storage device is a solid-state drive (SSD).

Example 17 may include a method for generating a non-volatile memory die topology comprising: scanning a plurality of non-volatile memory dies in a multi-die memory package to detect one or more defective non-volatile memory dies, wherein an individual non-volatile memory die of the plurality of non-volatile memory dies is defective if the individual non-volatile memory die has a number of bad blocks that exceeds a predefined threshold; associating one or more defective die indicators with one or more non-volatile memory die identifiers in the non-volatile memory die topology based at least in part on the scan; and storing the non-volatile memory die topology in a non-volatile memory.

Example 18 may include the subject matter of Example 17, or some other example herein, wherein scanning the plurality of non-volatile memory dies includes reading a one-time programmable page (OTP) page of each die to determine the number of bad blocks in each die.

Example 19 may include the subject matter of any one of Examples 17-18, or some other example herein, further comprising: receiving a scan command from a host, wherein scanning the plurality of non-volatile memory dies is performed in response to the scan command.

Example 20 may include the subject matter of any one of Examples 17-19, or some other example herein, further comprising: determining a number of good dies for each of a plurality of memory channels, wherein a particular die of the plurality of non-volatile memory dies is determined to be a good die in response to a determination that the particular die has a number of bad blocks that is less than or equal to the predefined threshold; and generate an indicator if the number of good dies does not meet one or more predetermined channel requirements.

Example 21 may include a data storage controller comprising: a non-volatile memory; and a processor coupled with the non-volatile memory to: read a die topology stored in the non-volatile memory; fetch a defective die list from the die topology, wherein the defective die list includes a list of dies that have a number of bad blocks that exceed a predefined threshold; and update a healthy die list that excludes one or more non-volatile memory dies from being accessed during read and write operations based at least in part on the defective die list, wherein the excluded one or more non-volatile memory dies are part of one or more multi-die memory packages, and wherein the healthy die list includes dies that do not have a number of bad blocks that exceed the predefined threshold.

Example 22 may include the subject matter of Example 21, or some other example herein, wherein the processor is to read the die topology in response to detection of a power-on operation of a data storage device that includes the data storage controller.

Example 23 may include the subject matter of any one of Examples 21-22, or some other example herein, wherein the one or more multi-die memory packages are NAND memory packages in a solid-state drive (SSD).

Example 24 may include the subject matter of any one of Examples 21-23, or some other example herein, wherein the processor is further to store the updated healthy die list in the non-volatile memory.

Example 25 may include the subject matter of any one of Examples 21-24, or some other example herein, wherein the processor is to read the die topology via a serial peripheral interface (SPI).Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions stored thereon that, when executed, result in actions of any of the above-described embodiments. Moreover, some embodiments may include apparatuses or systems having any suitable means for carrying out the various operations of the above-described embodiments.

Example 26 may include an apparatus comprising means for performing the method of any one of Examples 17-20, or some other example herein.

Example 27 may include a computer-readable medium comprising instructions stored thereon, that in response to execution of the instructions cause an electronic device to perform the method of any one of Examples 17-20, or some other example herein.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

We claim:

1. A data storage controller comprising:
a non-volatile memory; and
a processor coupled with the non-volatile memory to:
perform a scan of a plurality of non-volatile memory dies in a multi-die memory package to detect one or more defective non-volatile memory dies, wherein an individual non-volatile memory die of the plurality of non-volatile memory dies is defective if the individual non-volatile memory die has a number of bad blocks that exceeds a predefined threshold; and
store one or more defective die indicators in a die topology in the non-volatile memory based at least in part on the scan, wherein the one or more defective die indicators correspond to the one or more defective non-volatile memory dies.

2. The data storage controller of claim 1, wherein the non-volatile memory dies are NAND memory dies.

3. The data storage controller of claim 1, wherein the data storage controller includes a host interface and the processor is to perform the scan based at least in part on a scan command received from a host via the host interface.

4. The data storage controller of claim 1, wherein the predefined threshold is an input value associated with a stored configuration token.

5. The data storage controller of claim 1, wherein the processor is to read a one-time programmable (OTP) page of each die to determine the number of bad blocks in the die.

6. The data storage controller of claim 1, wherein the processor is also to determine a number of good dies for each of a plurality of memory channels, and generate an indicator in response to a determination that the number of good dies for each of the plurality of memory channels does not meet one or more predetermined channel requirements, wherein a particular die of the plurality of non-volatile memory dies is determined to be a good die in response to a determination that the particular die has a number of bad blocks that is less than or equal to the predefined threshold.

7. The data storage controller of claim 6, wherein the one or more predetermined channel requirements include a number of good dies expected for each channel, and the processor is to generate the indicator in response to a determination that the number of good dies in a channel is less than the number of good dies expected for the channel.

8. The data storage controller of claim 6, wherein the processor is also to:
generate one or more retired die indicators in response to a determination that the number of good dies in a channel is more than the number of good dies expected for the channel; and
store the one or more retired die indicators in the die topology.

9. The data storage controller of claim 1, wherein the processor is also to:
read the die topology from the non-volatile memory in response to detection of a power-on operation of a data storage device that includes the data storage controller;
fetch a defective die list that includes the one or more defective die indicators from the die topology; and
update a healthy die list that excludes one or more of the plurality of non-volatile memory dies from being accessed during read and write operations, based at least in part on the defective die list, wherein the healthy die list includes dies that do not have a number of bad blocks that exceed the predefined threshold.

10. The data storage controller of claim 1, wherein the data storage controller is a solid-state drive (SSD) controller.

11. A data storage device comprising:
a memory package having a plurality of non-volatile memory dies; and
a data storage controller to:
perform a scan of the plurality of non-volatile memory dies to detect one or more defective non-volatile memory dies, wherein an individual non-volatile memory die of the plurality of non-volatile memory dies is defective if the individual non-volatile memory die has a number of bad blocks that exceeds a predefined threshold; and
store one or more defective die indicators in a die topology in a non-volatile memory based at least in part on the scan, wherein the one or more defective die indicators correspond to the one or more defective non-volatile memory dies.

12. The data storage device of claim 11, wherein the memory package is a NAND memory package.

13. The data storage device of claim 11, wherein the data storage controller is also to perform the scan based at least in part on a scan command received from a host.

14. The data storage device of claim 11, wherein the data storage controller is to read a one-time programmable page (OTP) page of each die to determine the number of bad blocks in each die.

15. The data storage device of claim 11, wherein the data storage controller is also to determine a number of good dies for each of a plurality of memory channels, and generate an indicator in response to a determination that the number of good dies for each of the plurality of memory channels does not meet one or more predetermined channel requirements, wherein a particular die of the plurality of non-volatile memory dies is determined to be a good die in response to a determination that the particular die has a number of bad blocks that is less than or equal to the predefined threshold.

16. The data storage device of claim 11, wherein the data storage device is a solid-state drive (SSD).

17. A method for generating a non-volatile memory die topology comprising:
scanning a plurality of non-volatile memory dies in a multi-die memory package to detect one or more defective non-volatile memory dies, wherein an individual non-volatile memory die of the plurality of non-volatile memory dies is defective if the individual non-volatile memory die has a number of bad blocks that exceeds a predefined threshold;
associating one or more defective die indicators with one or more non-volatile memory die identifiers in the non-volatile memory die topology based at least in part on the scan; and
storing the non-volatile memory die topology in a non-volatile memory.

18. The method of claim 17, wherein scanning the plurality of non-volatile memory dies includes reading a one-time programmable page (OTP) page of each die to determine the number of bad blocks in each die.

19. The method of claim 17, further comprising: receiving a scan command from a host, wherein scanning the plurality of non-volatile memory dies is performed in response to the scan command.

20. The method of claim 17, further comprising:
determining a number of good dies for each of a plurality of memory channels, wherein a particular die of the plurality of non-volatile memory dies is determined to be a good die in response to a determination that the particular die has a number of bad blocks that is less than or equal to the predefined threshold; and
generate an indicator if the number of good dies does not meet one or more predetermined channel requirements.

21. A data storage controller comprising:
a non-volatile memory; and
a processor coupled with the non-volatile memory to:
read a die topology stored in the non-volatile memory;
fetch a defective die list from the die topology, wherein the defective die list includes a list of dies that have a number of bad blocks that exceed a predefined threshold; and
update a healthy die list that excludes one or more non-volatile memory dies from being accessed during read and write operations based at least in part on the defective die list, wherein the excluded one or more non-volatile memory dies are part of one or more multi-die memory packages, and wherein the healthy die list includes dies that do not have a number of bad blocks that exceed the predefined threshold.

22. The data storage controller of claim 21, wherein the processor is to read the die topology in response to detection of a power-on operation of a data storage device that includes the data storage controller.

23. The data storage controller of claim 21, wherein the one or more multi-die memory packages are NAND memory packages in a solid-state drive (SSD).

24. The data storage controller of claim 21, wherein the processor is further to store the updated healthy die list in the non-volatile memory.

25. The data storage controller of claim 21, wherein the processor is to read the die topology via a serial peripheral interface (SPI).
